(19) United States
(12) Patent Application Publication
(10) Pub. No.: US 2014/0162447 A1
(43) Pub. Date: Jun. 12, 2014

(54) FINFET HYBRID FULL METAL GATE WITH BORDERLESS CONTACTS

(71) Applicants: INTERNATIONAL BUSINESS MACHINES CORPORATION, Armonk, NY (US); GLOBALFOUNDRIES, INC., Grand Cayman (KY); RENESAS ELECTRONICS CORPORATION, Kawasaki (JP)

(72) Inventors: Lisa F. Edge, Watervliet, NY (US); Martin M. Frank, Dobbs Ferry, NY (US); Balasubramanian S. Haran, Watervliet, NY (US); Atsuro Inada, Clifton Park, NY (US); Sivananda K. Kanakasabapathy, Niskayuna, NY (US); Andreas Knorr, Wappingers Falls, NY (US); Vijay Narayanan, New York, NY (US); Vamsi K. Paruchuri, Clifton Park, NY (US); Soon-cheon Seo, Glenmont, NY (US)

(73) Assignees: INTERNATIONAL BUSINESS MACHINES CORPORATION, Armonk, NY (US); RENESAS ELECTRONICS CORPORATION, Kawasaki (JP); GLOBALFOUNDRIES, INC., Grand Cayman (KY)

(21) Appl. No.: 13/709,250

(22) Filed: Dec. 10, 2012

(51) Int. Cl. H01L 21/28

(52) U.S. Cl. CPC H01L 21/28008
USPC 438/586

(57) ABSTRACT

A method for fabricating a field effect transistor device includes patterning a fin on substrate, patterning a gate stack over a portion of the fin and a portion of an insulator layer arranged on the substrate, forming a protective barrier over the gate stack, a portion of the fin and a portion of the insulator layer, the protective barrier enveloping the gate stack, depositing a second insulator layer over portions of the fin and the protective barrier, performing a first etching process to selectively remove portions of the second insulator layer to define cavities that expose portions of source and drain regions of the fin without appreciably removing the protective barrier, and depositing a conductive material in the cavities.

### BACKGROUND

The present invention relates to field effect transistor (FET) devices, and more specifically, to FinFET devices.

FinFET devices include fins arranged on a substrate. A gate stack is arranged over a channel region of the fins. The fins partially define source and drain (active) regions and channel regions of the device.

### SUMMARY

According to an embodiment of the present invention, a method for fabricating a field effect transistor device includes patterning a fin on substrate, patterning a gate stack over a portion of the fin and a portion of an insulator layer arranged on the substrate, forming a protective barrier over the gate stack, a portion of the fin and a portion of the insulator layer, the protective barrier enveloping the gate stack, depositing a second insulator layer over portions of the fin and the protective barrier, performing a first etching process to selectively remove portions of the second insulator layer to define cavities that expose portions of source and drain regions of the fin without appreciably removing the protective barrier, and depositing a conductive material in the cavities.

According to another embodiment of the present invention, a method for fabricating a field effect transistor device includes patterning a fin on a substrate, depositing a dielectric layer over the fin and exposed portions of the insulator layer arranged on the substrate, depositing a silicon material layer over the dielectric layer, planarizing the silicon material layer, depositing a low resistivity metal layer over the silicon material layer, patterning the dielectric layer, the silicon material layer, and the low resistivity metal layer to define a gate stack over a portion of the fin and a portion of the insulator layer, forming a protective barrier over the gate stack, a portion of the fin and a portion of the insulator layer, the protective barrier enveloping the gate stack, depositing a second insulator layer over exposed portions of the fin and the protective barrier, performing a first etching process to selectively remove portions of the second insulator layer to define cavities that expose portions of source and drain regions of the device without appreciably removing the protective barrier, and depositing a conductive material in the cavities.

According to yet another embodiment of the present invention, a method for fabricating a field effect transistor device includes patterning a fin on an insulator layer, patterning a gate stack over a portion of the fin and a portion of the insulator layer, forming a protective barrier over the gate stack, a portion of the fin and a portion of the insulator layer, the protective barrier enveloping the gate stack, depositing a second insulator layer over exposed portions of the protective barrier, performing a first etching process to selectively remove portions of the second insulator layer to define cavities that expose portions of source and drain regions without appreciably removing the protective barrier, and depositing a conductive material in the cavities.

Additional features and advantages are realized through the techniques of the present invention. Other embodiments and aspects of the invention are described in detail herein and are considered a part of the claimed invention. For a better understanding of the invention with the advantages and the features, refer to the description and to the drawings.

### BRIEF DESCRIPTION OF THE SEVERAL VIEWS OF THE DRAWINGS

The subject matter which is regarded as the invention is particularly pointed out and distinctly claimed in the claims at the conclusion of the specification. The forgoing and other features, and advantages of the invention are apparent from the following detailed description taken in conjunction with the accompanying drawings in which:

FIG. 1 illustrates a top view of a substrate.

FIG. 2 illustrates a side view of the substrate.

FIG. 3 illustrates a top view of the resultant structure following the patterning of a plurality of fins.

FIG. 4 illustrates a side cut-away view of the resultant structure along the line 4 (of FIG. 3).

FIG. 5 illustrates a top view following the deposition of a dielectric layer.

FIG. 6 illustrates a cut away view along the line 6 of FIG. 5.

FIG. 7 illustrates the formation of a semiconductor layer.

FIG. 8 illustrates a top view of the resultant structure following a patterning and etching process.

FIG. 9 illustrates a cut away view along the line 9 of FIG. 8.

FIG. 10 illustrates a cut away view along the line 10 of FIG. 8.

FIG. 11 illustrates a top view following the deposition of a layer of spacer material.

FIG. 12 illustrates a cut away view along the line 12 of FIG. 11.

FIG. 13 illustrates a cut away view along the line 13 of FIG. 11.

FIG. 14 illustrates a top view of the resultant structure following an epitaxial growth process.

FIG. 15 illustrates a side cut-away view of the resultant structure along the line 15 of FIG. 14.

FIG. 16 illustrates a side cut-away view of the resultant structure along the line 15 of FIG. 14 following the formation of an insulator layer.

FIG. 17 illustrates a top view following the deposition of an optical dispersal layer (ODL) and resist patterning for source drain contact holes on the insulator layer.

FIG. 18 illustrates a cut away view along the line 18 of FIG. 17.

FIG. 19 illustrates the resultant structure following an etching process.

FIG. 20 illustrates a top view following the deposition and of an ODL and resist patterning for gate contact hole.

FIG. 21 illustrates a cut away view along the line 21 of FIG. 20.

FIG. 22 illustrates a cut away view along the line 22 of FIG. 20.

FIG. 23 illustrates the resultant structure following an etching process.

FIG. 24. illustrates a top view following the formation of conductive contacts.

FIG. 25 illustrates a cut away view along the line 25 of FIG. 24.

FIG. 26 illustrates a cut away view along the line 26 of FIG. 24.

FIG. 27 illustrates a side view of a substrate.

FIG. 28 illustrates the resultant structure following the patterning of fins

FIG. 29 illustrates the resultant structure following the formation of an insulator layer.

### DETAILED DESCRIPTION

Disclosed herein is a low resistivity metal gate electrode structure including a low resistivity metal layer, a barrier layer and a silicon layer, wherein the low resistivity metal layer may, for example, be formed of tungsten, and wherein the barrier layer may, for example, be formed of TaAlN, TiAlN, TiN, TaN, WN, or of a bilayer such as WN on Ti, and wherein the barrier layer is intermediate the low resistivity metal layer and the silicon layer. Advantageously, when the low resistivity metal layer is formed of tungsten and the barrier layer is formed of TaAlN, the gate electrode structure of the present disclosure has been found to be thermally stable even after annealing at 1000° C. Moreover, the sheet resistivity of the metal layer on TaAlN is about 11 to 15 ohm/square at a thickness of about 125 Angstroms, which was more than 50% lower than a similar gate electrode structure including TiN or TaN instead of TaAlN. The methods and resultant structures described herein are directed towards a full metal gate device with borderless contacts.

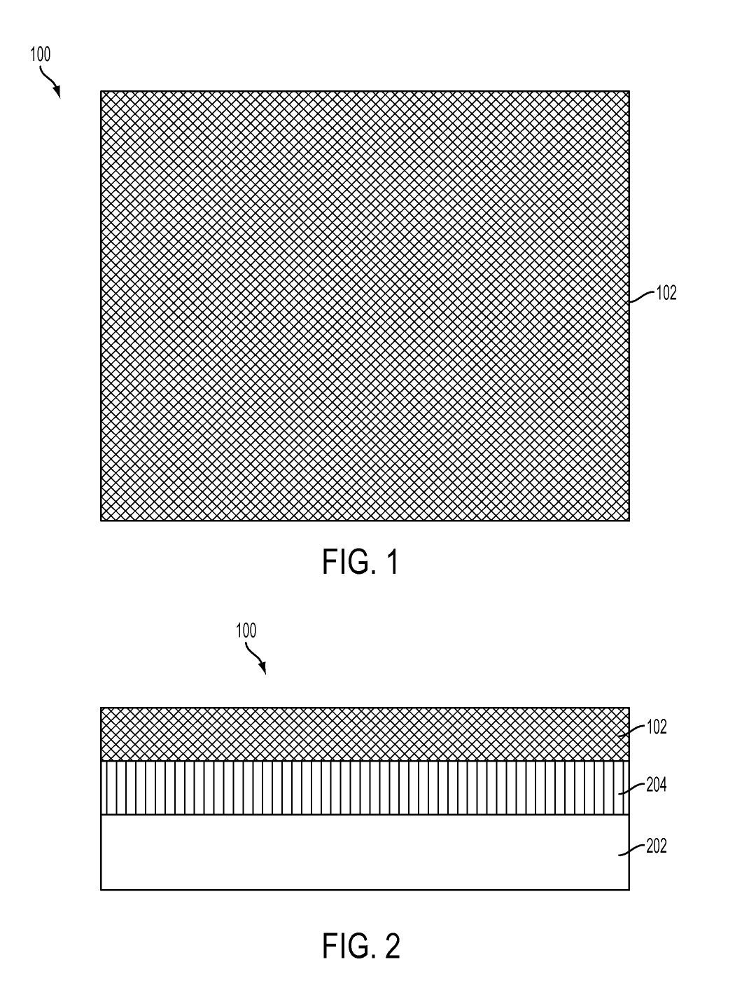

In this regard, FIG. 1 illustrates a top view of a substrate 100 that includes a hardmask layer 102 that may include, for example an oxide material. FIG. 2 illustrates a side view of the substrate 100 showing an insulator layer 202 such as, for example a buried oxide (BOX) layer disposed beneath a semiconductor layer 204. The semiconductor layer 204 can be silicon, which in this example would comprise a silicon-on-insulator layer or more generally a semiconductor-on-insulator (SOI) layer. However, also other semiconductor materials such as germanium, silicon-germanium alloy, silicon carbon alloy, silicon-germanium-carbon alloy, gallium arsenide, indium arsenide, indium phosphide, III-V compound semiconductor materials, II-VI compound semiconductor materials, organic semiconductor materials, and other compound semiconductor materials are possible.

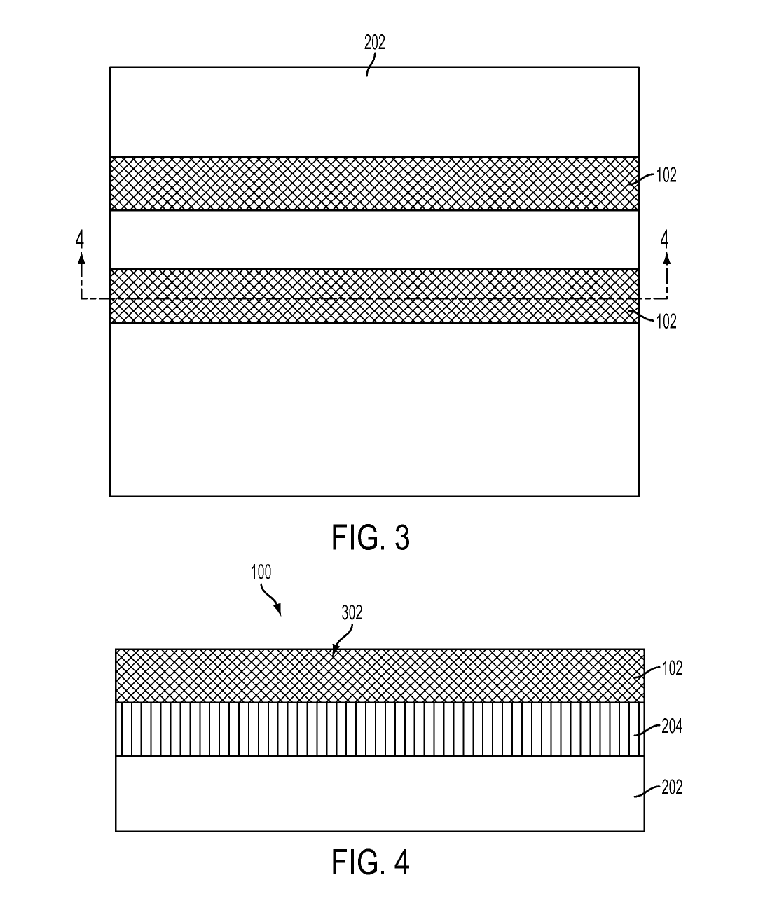

FIG. 3 illustrates a top view of the resultant structure following the patterning of a plurality of fins 302 by removing portions of the hardmask layer 102 and the SOI layer 102 to expose portions of the insulator layer 202. FIG. 4 illustrates a side cut-away view of the resultant structure along the line 4 (of FIG. 3).

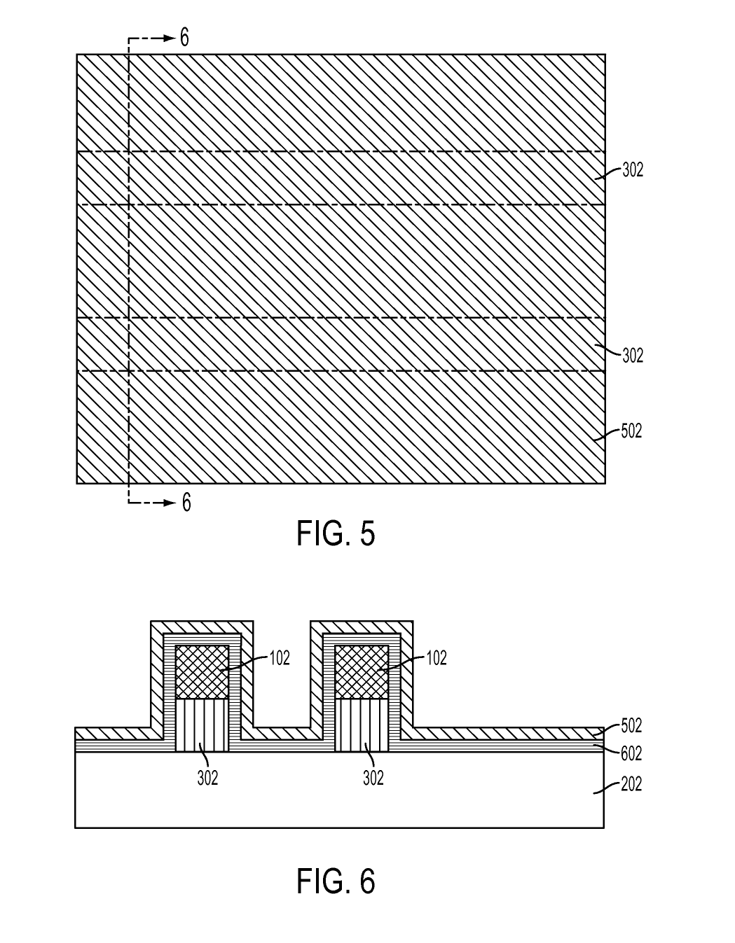

FIG. 5 illustrates a top view and FIG. 6 illustrates a cut away view along the line 6 (of FIG. 5) following the deposition of a dielectric layer 602 (of FIG. 6) and a gate metal layer 502 over the fins 302 and the insulator layer 202 (of FIG. 6).

The gate electrode structure can further include an oxide or oxynitride layer (not shown), which is also referred to as the interfacial layer upon which the dielectric layer 602 is deposited. For example, the process step for forming an oxide layer may include wet chemical oxidation. An exemplary wet chemical oxidation process may include treating the cleaned semiconductor surface (such as a semiconductor surface treated with hydrofluoric acid) with a mixture of ammonium hydroxide, hydrogen peroxide and water (in a 1:1:5 ratio) at 65° C. Alternately, the oxide layer can also be formed by treating the HF-last semiconductor surface in ozonated aqueous solutions, with the ozone concentration usually varying from, but not limited to: 2 parts per million (ppm) to 40 ppm. The oxide layer helps minimize mobility degradation in the fin 302 due to the high-k dielectric material. In case the substrate semiconductor layer is a silicon layer, the oxide layer may be a silicon oxide layer. Typically, the thickness of the oxide layer is from about 5 Angstroms to about 15 Angstroms, although lesser and greater thicknesses are also contemplated herein. Other methods of forming an interfacial oxide layer, as well as other interfacial layers, are also contemplated herein.

The dielectric layer 602 generally includes a dielectric metal oxide. In one embodiment, the dielectric layer comprises a high-k dielectric material having a dielectric constant that is greater than the dielectric constant of silicon oxide. In one embodiment, the dielectric layer 602 has a dielectric constant of greater than 4.0, typically greater than 10, as measured in a vacuum. Examples of such dielectric materials having a dielectric constant of greater than 4.0 include, but are not limited to, silicon nitride, silicon oxynitride, metal oxides, metal nitrides, metal oxynitrides and/or metal silicates. In one embodiment, the dielectric layer 602 comprises HfO₂, ZrO₂, Al₂O₃, TiO₂, La₂O₃SrTiO₃, LaAlO₃, Y₂O₃ or multilayered stacks thereof. In another embodiment of the disclosure, the dielectric layer 502 is a Hf-based gate dielectric including HfO₂, hafnium silicate and hafnium silicon oxynitride, optionally comprising additional metal ions such as, for example, Al, La, Dy, Sr, or Ba. Structures without a high-k dielectric layer, instead including, e.g., an oxide such as silicon oxide (SiO₂) or an oxynitride such as silicon oxynitride (SiON), are also contemplated herein.

The dielectric layer 602 and the gate metal layer 502 may be formed by methods including, for example, chemical vapor deposition (CVD), atomic layer deposition (ALD), molecular beam deposition (MBD), pulsed laser deposition (PLD), liquid source misted chemical deposition (LSMCD), sputter deposition, and the like.

The thickness of the as deposited high-k gate dielectric layer 602 may vary depending on the dielectric material employed as well as the process used to form the same. The thickness of the as-deposited high-k gate dielectric 602 is from about 5 Angstroms to about 200 Angstroms, and more specifically with a thickness from about 10 Angstroms to about 100 Angstroms. If the dielectric layer 602 is silicon dioxide or silicon oxynitride, the thickness of the gate dielectric layer 602 would include the thickness of the relatively thin interfacial oxide layer.

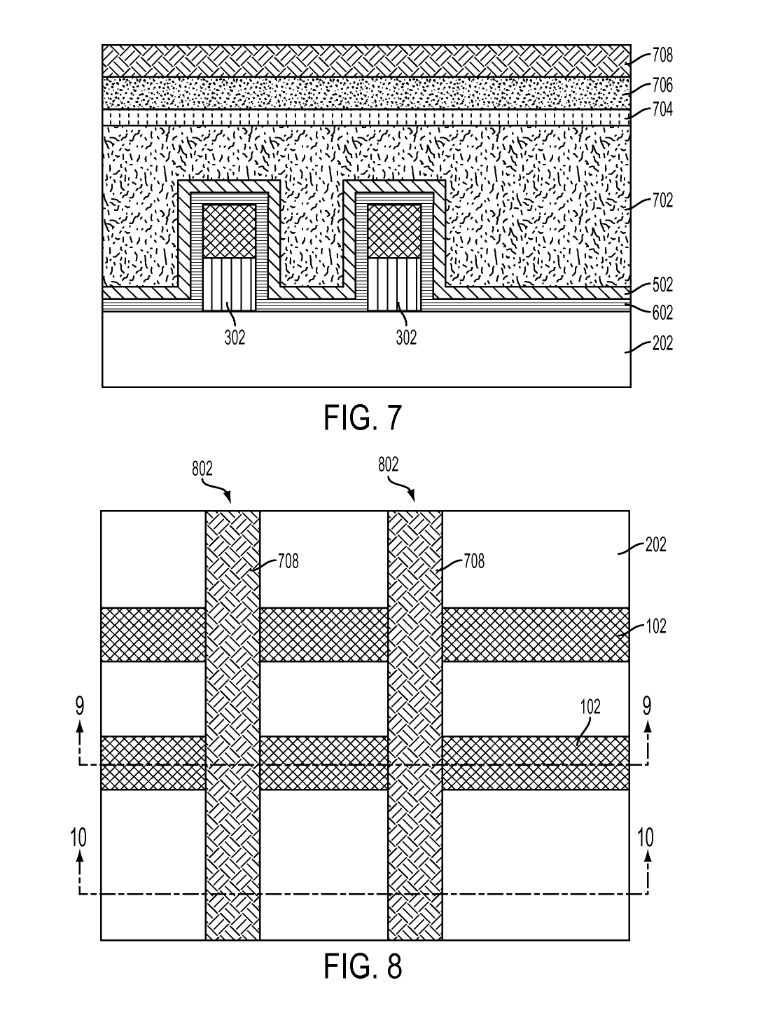

FIG. 7 illustrates the formation of a semiconductor layer 702, such as, for example, amorphous silicon (α-polysilicon) or polycrystalline silicon (polysilicon) and may be deposited by chemical vapor deposition process or other appropriate process over the gate metal layer 502. The silicon layer typically has a thickness of about 30 Angstroms to about 1000 Angstroms. The semiconductor layer 702 is planarized by for example, chemical mechanical polishing (CMP) following deposition.

A barrier layer 704 is deposited onto the semiconductor layer 702. The barrier layer 704 may for example be a material selected from the group consisting of titanium aluminum nitride (TiAlN), tantalum aluminum nitride (TaAlN), titanium nitride (TiN), tantalum nitride (TaN), tungsten nitride (WN), or it may be a bilayer such as WN on titanium (Ti). The barrier layer is commonly deposited by physical vapor deposition, sputtering, thermal chemical vapor deposition, or plasma enhanced chemical vapor deposition processes. When the barrier layer is a material selected from the group consisting of titanium aluminum nitride (TiAlN), tantalum aluminum nitride (TaAlN), the aluminum content may range from about 5 to about 40 atomic % based on the total composition. An appropriate nitrogen content may be between about 10 and 50 atomic %.

Optionally, the barrier layer 704 may be subjected to air exposure or any other oxidizing treatment to introduce oxygen atoms as may be desired for some applications. The barrier layer 704 is at an exemplary thickness of about 10 Angstroms to about 500 Angstroms, and in other embodiments, a thickness from about 25 Angstroms to about 200 Angstroms.

A low resistivity metal layer 706 is deposited onto the barrier layer 704. When the low resistivity metal layer is tungsten and the barrier layer is a material selected from the group consisting of titanium aluminum nitride (TiAlN), tantalum aluminum nitride (TaAlN), the barrier layer 704 allows for the formation of much larger tungsten grains than, for example, on a TiN or TaN layer. As a result, lower grain boundary scattering can be expected resulting in lower sheet resistance.

The low resistivity metal layer 706 can optionally also contain smaller amounts of other elements, either immediately after low resistivity metal deposition or after device fabrication, where the amount of other elements may be lower than about 10 atomic percent. The low resistivity metal layer may have any thickness. For most applications, it may measure approximately 10 to 1000 Angstroms, and more particularly approximately 50 to 500 Angstroms in thickness.

An optional capping layer 708 can be deposited onto the low resistivity metal layer 706. The capping layer 702 can be made of any material. For many applications, the optional capping layer 708 may comprise an insulating compound such as silicon nitride (Si₃N₄), aluminum oxide, or hafnium oxide, and measure approximately 10 to 500 Angstroms in thickness. The capping layer 708 may be formed by a deposition process, e.g., atomic layer deposition, PECVD (plasma-enhanced CVD), MOCVD (metallorganic CVD), MLD (molecular layer deposition), RTCVD (rapid thermal CVD), ALD, sputtering, or any other deposition method. Chemical vapor deposition processes may be performed at elevated temperatures. For example, RTCVD of silicon nitride films may be performed at temperatures greater than 500° C. Physical deposition processes such as sputtering may be performed at lower temperatures, for example at room temperature.

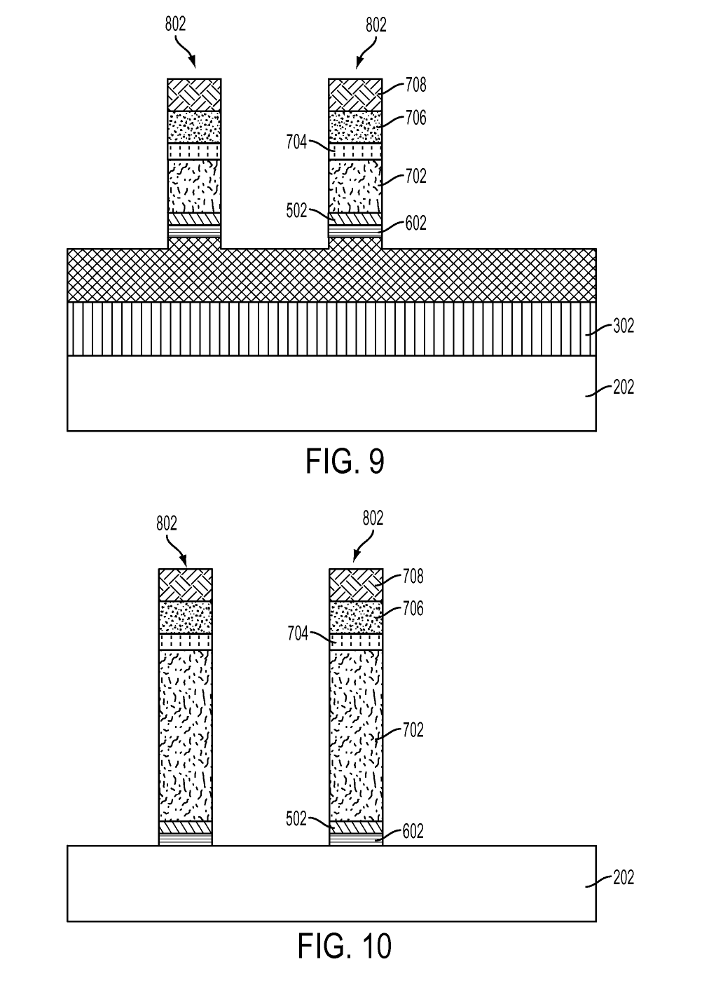

FIG. 8 illustrates a top view, FIG. 9 illustrates a cut away view along the line 9 (of FIG. 8), and FIG. 10 illustrates a cut away view along the line 10 (of FIG. 8) of the resultant structure following a patterning and etching process such as, for example, a reactive ion etching (RIE) process that patterns the gate stacks 802. The etching process removes the exposed portions of the capping layer 708, low resistivity metal layer 706, the barrier layer 704, the semiconductor layer 702, gate metal layer 502, and the dielectric layer 602 and exposes portions of the insulator layer 202. The patterning process may remove exposed portions of the hardmask layer 102.

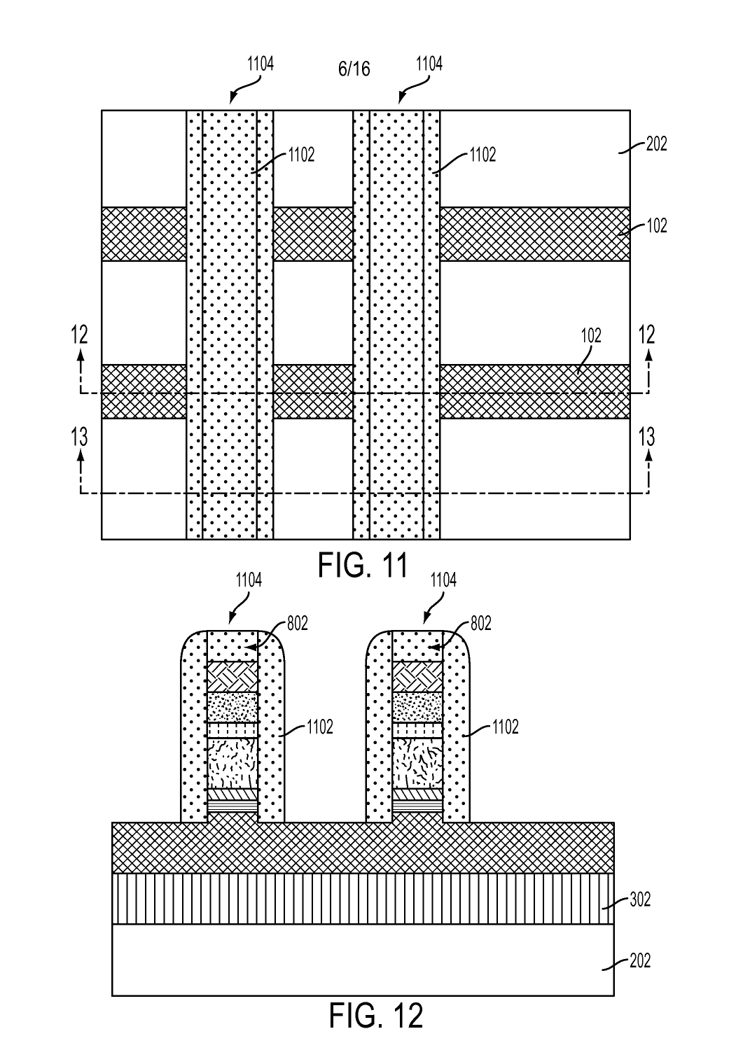

FIG. 11 illustrates a top view, FIG. 12 illustrates a cut away view along the line 12 (of FIG. 11), and FIG. 13 illustrates a cut away view along the line 13 (of FIG. 11) of following the deposition of a layer of spacer material such as, for example, silicon nitride (Si₃N₄), aluminum oxide, or hafnium oxide using a suitable deposition process such as, for example, a similar process used to deposit the capping layer 708 followed by an etching process that removes portions of the spacer material define spacers 1102. The spacers 1102 and the capping layer 708 define a protective barrier 1104 over the gate stack 802.

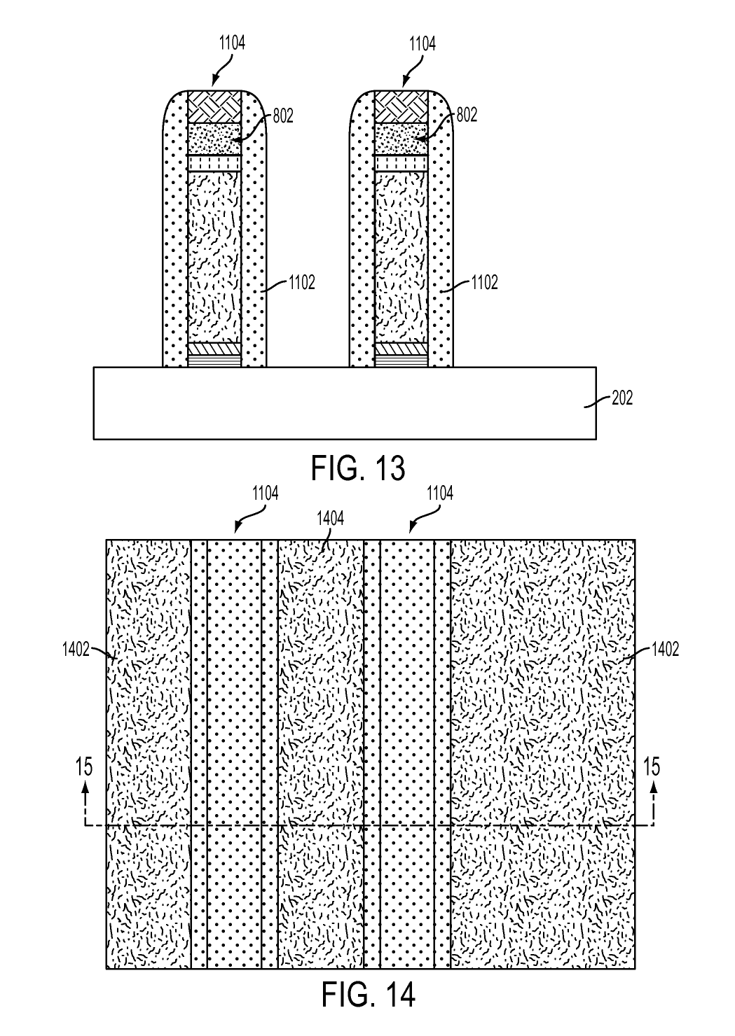

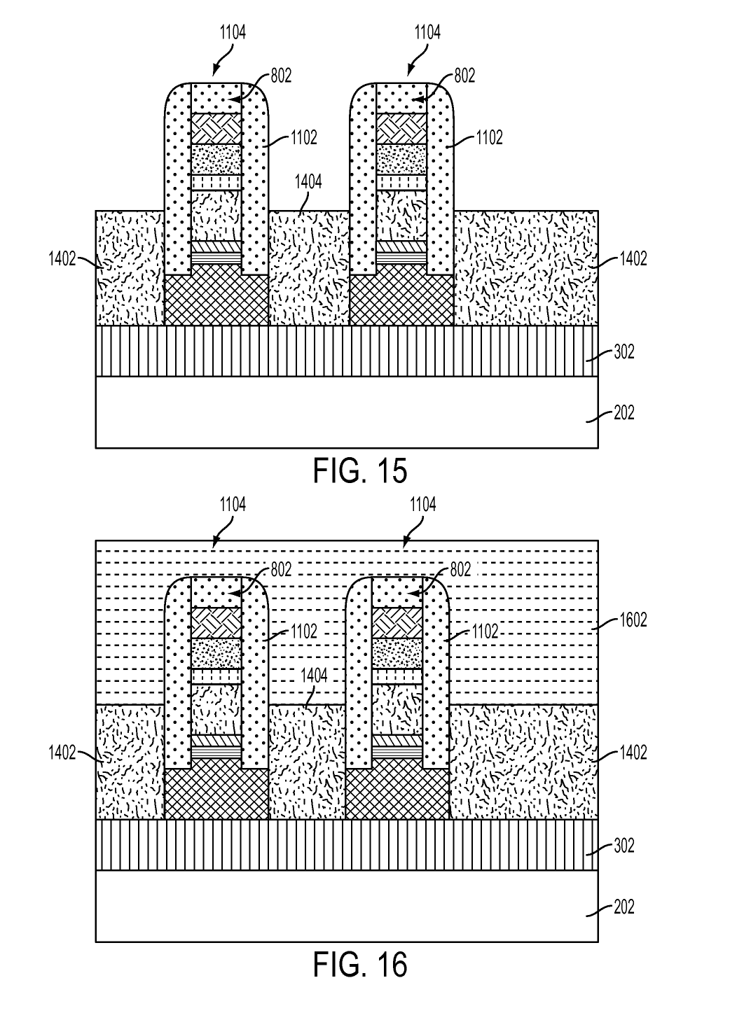

FIG. 14 illustrates a top view of the resultant structure following an epitaxial growth process of a semiconductor material such as, for example a silicon or germanium material that is grown from the exposed portions of the fins 302 (of FIG. 12). The semiconductor material may be in-situ doped with dopants to provide for source and drain regions 1402 and 1404 respectively of the resultant devices. FIG. 15 illustrates a side cut-away view of the resultant structure along the line 15 (of FIG. 14). Prior to the formation of the source and drain regions 1402 and 1404 using epitaxial growth process, exposed portions of the hardmask layer 102 is removed from the fins 302.

FIG. 16 illustrates a side cut-away view of the resultant structure along the line 15 (of FIG. 14) following the formation of an insulator layer 1602 such as, for example an oxide later over the source and drain regions 1402 and 1404, the protective barrier 1102 over the gate stack 1004. Once the insulator layer 1602 is deposited the insulator layer 1602 may be planarized by, for example, a CMP process.

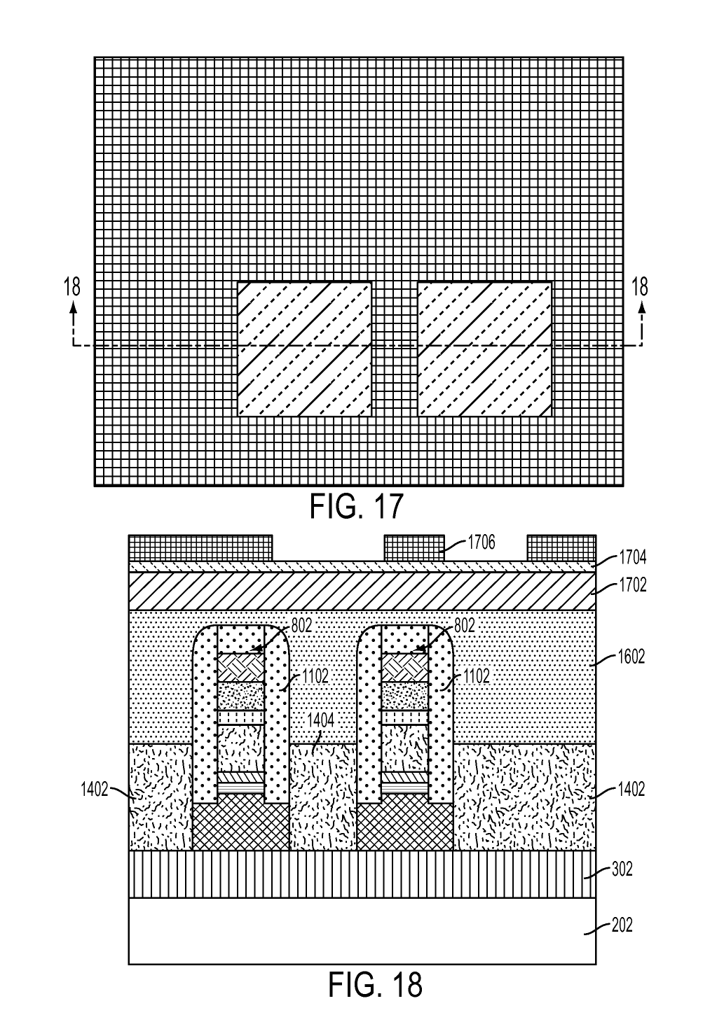

FIG. 17 illustrates a top view and FIG. 18 illustrates a cut away view along the line 18 (of FIG. 17) following the deposition of an optical dispersal layer (ODL) 1702 on the insulator layer 1602. A Si antireflective coating (SiARC) layer 1704 is deposited on the ODL 1702, and a photolithographic resist layer 1706 is patterned on the SiARC layer 1704.

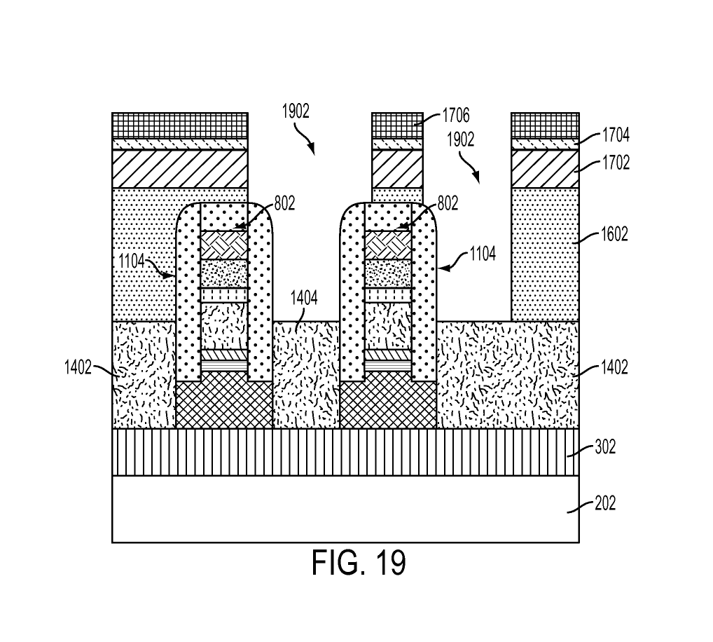

FIG. 19 illustrates the resultant structure following an etching process. The etching process is selective such that the protective barrier 1104 is not appreciably removed. The etching process removes exposed portions of ODL 1702, the SiARC layer 1704 and the insulator layer 1602 to form cavities 1902 that expose the source and drain regions 1402 and 1404. Following or during the etching process, the ODL 1702, SiARC layer 1704, and the photolithographic resist layer 1706 are removed. After the patterning, resist, SiARC layer 1704, and ODL 1702 are removed.

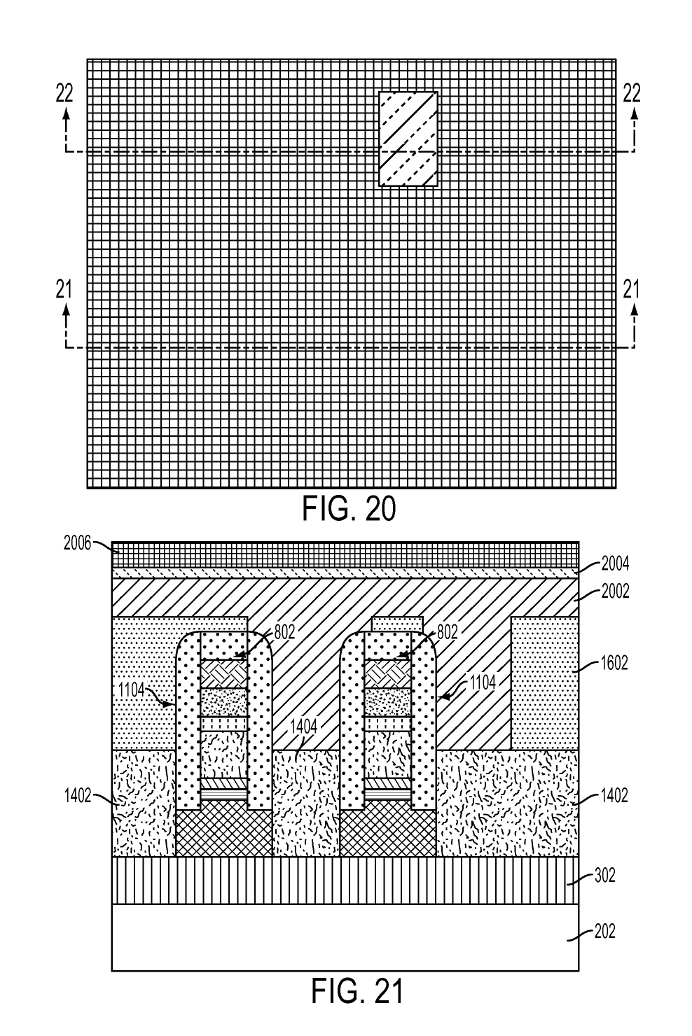

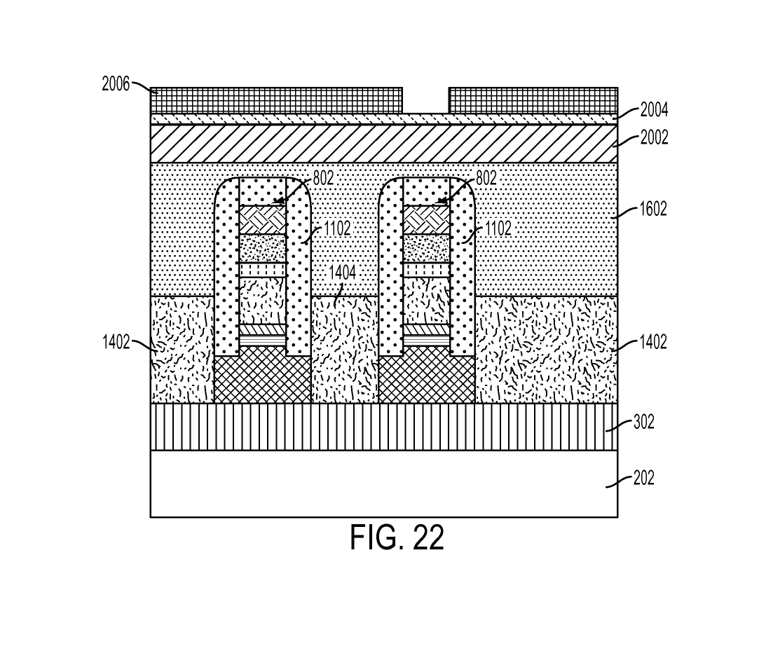

FIG. 20 illustrates a top view, FIG. 21 illustrates a cut away view along the line 21 (of FIG. 20), and FIG. 22 illustrates a cut away view along the line 22 (of FIG. 20) following the deposition and planarization of an ODL 2002, the deposition of a SiARC layer 2004 on the ODL 2002, and the patterning of a photolithographic resist layer 2006 on the SiARC layer 2004.

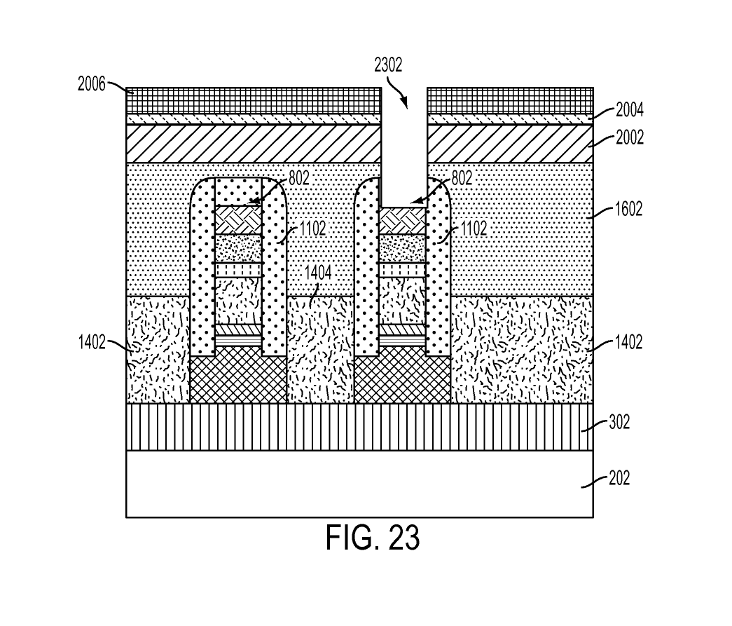

FIG. 23 illustrates the resultant structure following an etching process that is operative to remove exposed portions of the ODL 2002, the SiARC layer 2004, the insulator layer 1602 and the protective barrier 1104 to form a cavity 2302 that exposes the gate stack 802.

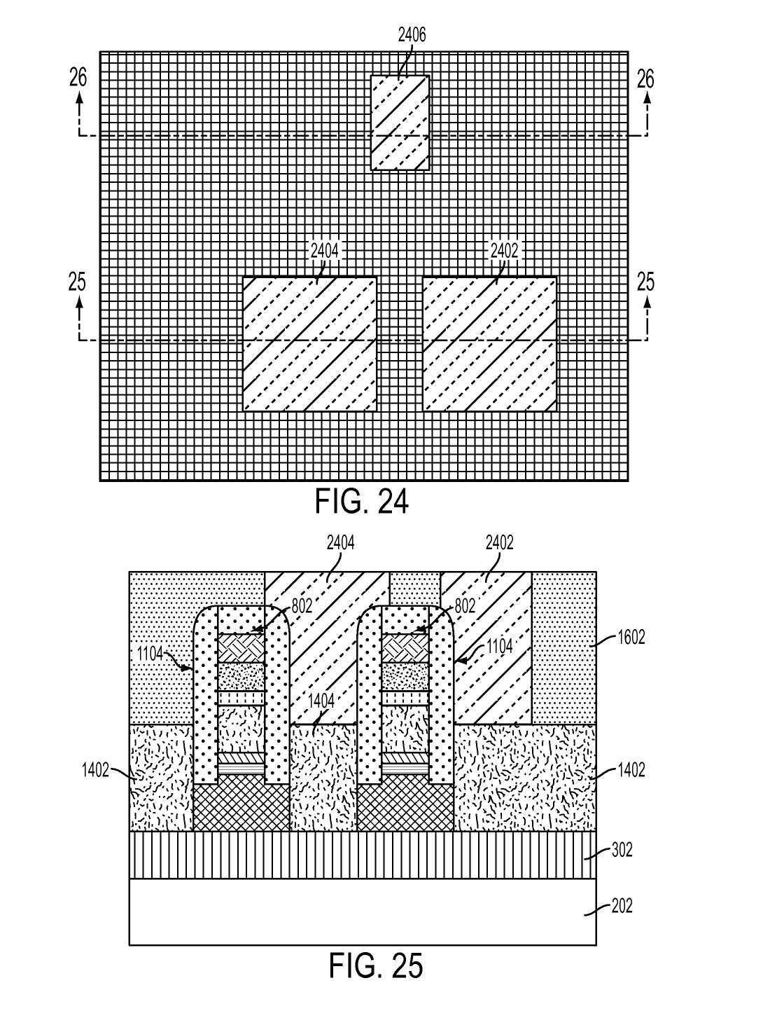

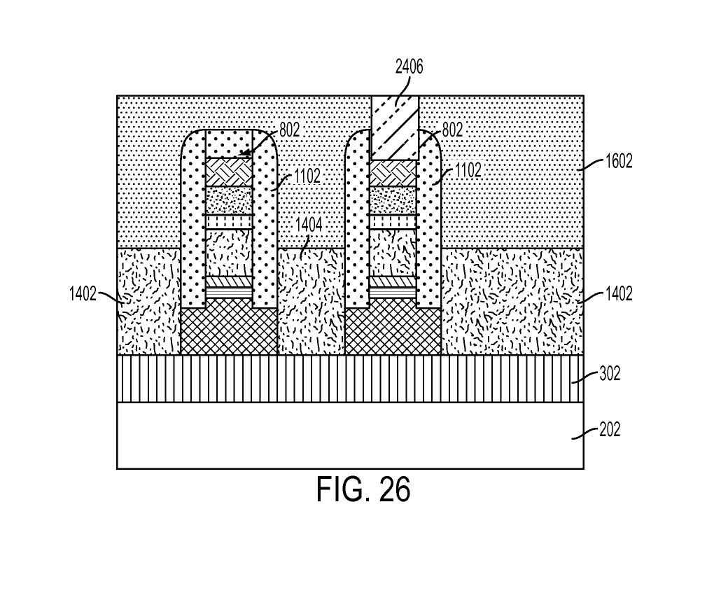

FIG. 24. illustrates a top view, FIG. 25 illustrates a cut away view along the line 25 (of FIG. 24), and FIG. 26 illustrates a cut away view along the line 26 (of FIG. 24) of the resultant structure following the removal of the ODL 2002, the SiARC layer 2004, and the resist layer 2006 and the deposition of a conductive contact material followed by a planarization process. The conductive contact material fills the cavities 1902 (of FIGS. 19) and 2302 (of FIG. 23). The planarization process defines conductive contacts 2404 and 2402 for the source and drain regions 1402 and 1404, and conductive contact 2406 for the gate contact. The conductive material may include, for example a conductive metal such as copper, ruthenium, palladium, platinum, cobalt, nickel, ruthenium oxide, tungsten, aluminum, manganese, cobalt, cobalt tungsten, cobalt tungsten phosphorus, titanium, tantalum, hafnium zirconium, transition metal elements, rare earth elements, a metal carbide, carbon nano tubes, a conductive metal oxide and combinations thereof.

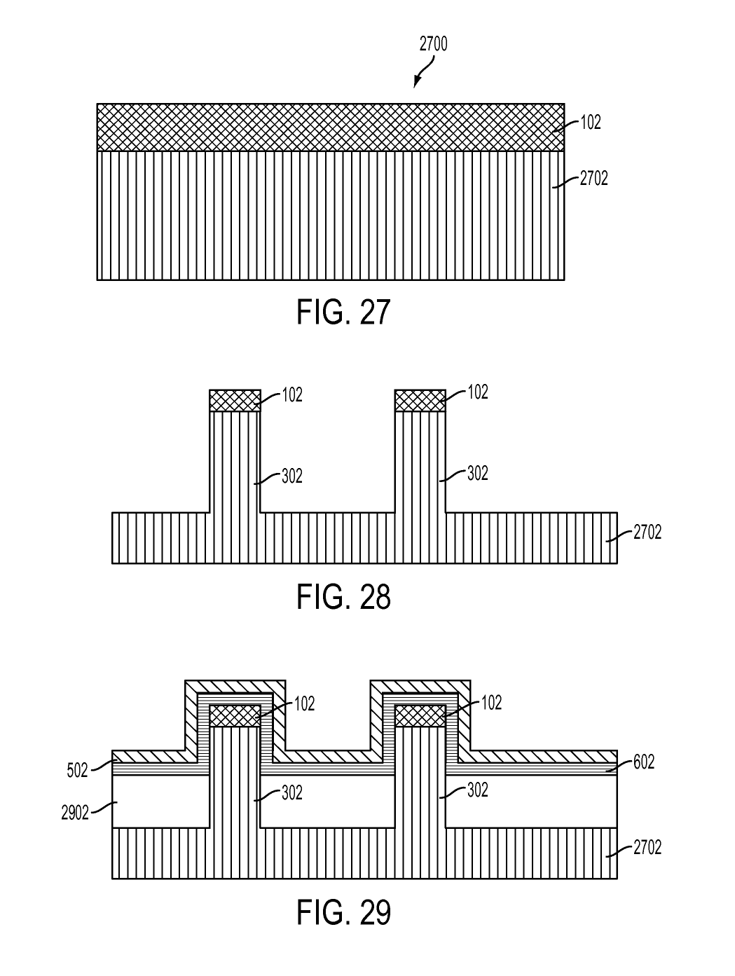

The exemplary embodiments described above include a SOI substrate. FIGS. 27-29 illustrate an alternate exemplary embodiment of the methods and devices described above that includes the formation of the devices on a bulk semiconductor substrate. In this regard, FIG. 27 illustrates a side view of a substrate 2700 that includes semiconductor layer 2702 and a hardmask layer 102 arranged on the semiconductor layer 2702.

FIG. 28 illustrates the resultant structure following the patterning of fins 302 in the semiconductor layer 2702. The patterning of the fins 302 may be performed by, for example, a photolithographic patterning and etching process.

FIG. 29 illustrates the resultant structure following the formation of an insulator layer 2902 over portions of the semiconductor layer 2702. The insulator layer 2902 may include, for example, an oxide material. Following the formation of the insulator layer 2902, a dielectric layer 602 and a gate metal layer 502 are over the fins 302 and the insulator layer 2902. Following the deposition of the gate metal layer 502 the methods similar to the methods described above in FIGS. 7-26 may be performed to form a FinFET device on a bulk semiconductor substrate.

The illustrated methods and resultant structures provide a hybrid full metal gate FinFET device having self-aligned contacts.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated

The flow diagrams depicted herein are just one example. There may be many variations to this diagram or the steps (or operations) described therein without departing from the spirit of the invention. For instance, the steps may be performed in a differing order or steps may be added, deleted or modified. All of these variations are considered a part of the claimed invention.

While the preferred embodiment to the invention had been described, it will be understood that those skilled in the art, both now and in the future, may make various improvements and enhancements which fall within the scope of the claims which follow. These claims should be construed to maintain the proper protection for the invention first described.

1. A method for fabricating a field effect transistor device, the method comprising:
patterning a fin on substrate;
patterning a gate stack over a portion of the fin and a portion of an insulator layer arranged on the substrate, wherein the gate stack includes a dielectric layer disposed over a channel region of the fin; a silicon material layer selected from the group consisting of amorphous silicon and polysilicon disposed over and in contact with the dielectric layer; a TaAN or TiAlN barrier layer disposed over and in contact with the silicon material layer; and a low resistivity metal layer formed of tungsten disposed over and in contact with the barrier layer, wherein the tungsten metal layer has a sheet resistivity of about 11 to about 15 ohm/square at a thickness of about 125 Angstroms;
forming a protective barrier over the gate stack, a portion of the fin and a portion of the insulator layer, the protective barrier enveloping the gate stack;
depositing a second insulator layer over portions of the fin and the protective barrier;
performing a first etching process to selectively remove portions of the second insulator layer to define cavities that expose portions of source and drain regions of the fin without appreciably removing the protective barrier; and
depositing a conductive material in the cavities.

2-8. (canceled)

9. The method of claim 1, wherein the protective barrier includes a metal oxide material.

10. The method of claim 1, wherein the protective barrier includes spacers arranged adjacent to the gate stack and a capping layer arranged over and in contact with a tungsten layer of the gate stack.

11. The method of claim 1, wherein the second insulator layer includes an oxide material.

12. A method for fabricating a field effect transistor device, the method comprising:
patterning a fin on a substrate;
depositing a dielectric layer over the fin and exposed portions of an insulator layer arranged on the substrate;
depositing a silicon material layer over the dielectric layer, wherein the silicon material layer is selected from the group consisting of amorphous silicon and polysilicon;
planarizing the silicon material layer;
depositing a TaAlN or TiAlN barrier layer over the silicon material layer, wherein the aluminum content is 5 to 40 atomic percent based on a composition of the barrier layer;
depositing a low resistivity metal layer of tungsten over the silicon material layer, wherein the tungsten metal layer has a sheet resistivity of about 11 to about 15 ohm/square at a thickness of about 125 Angstroms;
patterning the dielectric layer, the silicon material layer, and the low resistivity metal layer to define a gate stack over a portion of the fin and a portion of the insulator layer;
forming a protective barrier over the gate stack, a portion of the fin and a portion of the insulator layer, the protective barrier enveloping the gate stack;
depositing a second insulator layer over exposed portions of the fin and the protective barrier;
performing a first etching process to selectively remove portions of the second insulator layer to define cavities that expose portions of source and drain regions of the device without appreciably removing the protective barrier; and
depositing a conductive material in the cavities.

13. The method of claim 12, wherein the dielectric layer includes a high K material.

14. The method of claim 12, wherein the protective barrier includes a nitride material.

15. The method of claim 12, wherein the protective barrier includes spacers arranged adjacent to the gate stack and a capping layer arranged over and in contact with a tungsten layer of the gate stack.

16. The method of claim 12, wherein the second insulator layer includes an oxide material.

17. A method for fabricating a field effect transistor device, the method comprising:
patterning a fin on an insulator layer;
patterning a gate stack over a portion of the fin and a portion of the insulator layer, wherein the gate stack includes a dielectric layer disposed over a channel region of the fin; a silicon material layer selected from the group consisting of amorphous silicon and polysilicon disposed over and in contact with the dielectric layer; a TaAlN or TiAlN barrier layer disposed over and in contact with the silicon material layer; and a low resistivity metal layer formed of tungsten disposed over and in contact with the barrier layer, wherein the tungsten metal layer has a sheet resistivity of about 11 to about 15 ohm/square at a thickness of about 125 Angstroms;
forming a protective barrier over the gate stack, a portion of the fin and a portion of the insulator layer, the protective barrier enveloping the gate stack;
depositing a second insulator layer over exposed portions of the protective barrier;
performing a first etching process to selectively remove portions of the second insulator layer to define cavities that expose portions of source and drain regions without appreciably removing the protective barrier; and
depositing a conductive material in the cavities.

18-20. (canceled)
